(19) United States
(12) Patent Application Publication
(10) Pub. No.: US 2018/0159532 A1
(43) Pub. Date: Jun. 7, 2018

(54) MEASURING ELECTRODE FOR A CAPACITIVE PROXIMITY SENSOR OF A MOTOR VEHICLE

(71) Applicant: Brose Fahrzeugteile GmbH & Co. Kommanditgesellschaft, Bamberg, Bamberg (DE)

(72) Inventors: Florian Pohl, Ebersdorf (DE); Markus Korder, Ebensfeld (DE)

(21) Appl. No.: 15/835,018

(22) Filed: Dec. 7, 2017

(30) Foreign Application Priority Data
Dec. 7, 2016 (DE) 10 2016 123 646.2

(51) Int. Cl. H03K 17/955; H01B 13/06; H01B 13/00

(52) U.S. Cl. CPC H03K 17/955; E05Y 2900/50; H01B 13/0036; H01B 13/06

(57) ABSTRACT

The disclosure relates to a measurement electrode for a capacitive proximity sensor of a motor vehicle, having an electrical conductor structure and having a flat carrier structure for holding the conductor structure, where a plurality of threading openings are provided in the carrier structure, at least one conductor of the conductor structure being threaded through said plurality of threading openings.

### CLAIM OF PRIORITY

This application claims the benefit of German Patent application No. DE 10 2016 123 646.2 filed on Dec. 7, 2016, the disclosure of which is incorporated herein by reference.

### FIELD OF THE TECHNOLOGY

The disclosure relates to a measurement electrode for a capacitive proximity sensor of a motor vehicle, to a capacitive proximity sensor having a measurement electrode of this kind, to a bodywork component of a motor vehicle, to which a proximity sensor of this kind can be fastened, and to a method for producing a measurement electrode of this kind.

### BACKGROUND

The capacitive proximity sensor in question can be used for a very wide variety of applications. In the present case, the focus is on the sensor-assisted detection of operator control events. An operator control event which is to be detected can be, for example, a person approaching the motor vehicle, a predetermined movement of a body part, in particular of a foot, of a person, or the like. The sensor-assisted detection of operator control events of this kind triggers corresponding control-related responses, for example the motorized opening of the trunk lid of the motor vehicle.

The known measurement electrode (DE 10 2013 110 866 A1), from which the disclosure proceeds, is associated with a capacitive proximity sensor of a motor vehicle. The measurement electrode is formed by at least one flat conductor which is designed, for example, as an insulated copper strip. A flat conductor of this kind is generally fabricated from a continuous material. This is effective in respect of production, but leads to restrictions in the design of the measurement electrode. A first restriction is due to the shaping of the flat conductor of the known measurement electrode being fixedly prespecified. This leads to more copper material generally being used than is required from a technical point of view. A second restriction is that special plugs have to be provided for the purpose of making contact with the flat conductors which are generally comparatively broad, said special plugs leading to correspondingly high material and assembly costs.

### SUMMARY

The disclosure is based on the problem of configuring and developing the known measurement electrode in such a way that the flexibility when designing the measurement electrode is increased and, at the same time, the production costs are reduced.

The above problem is solved by the features described herein in the case of a measurement electrode for a capacitive proximity sensor of a motor vehicle.

An important point is the fundamental consideration that at least one conductor of the conductor structure can be secured to a flat carrier structure by the relevant conductor being threaded through a plurality of threading openings which already exist in the carrier structure. Since the threading openings are already present in the carrier structure before the threading, the threading openings can be designed to be large enough that the threading can be performed largely without force. This allows automated threading of the at least one conductor of the conductor structure in a particularly simple manner

The term “threading” is intended to be understood in a broad sense in the present case. It relates very generally to the relevant conductor, for example an end of the conductor or a loop which is formed by the conductor, entering the threading opening.

The solution as proposed allows the design and size of the measurement electrode to be adjusted in a simple manner by the threading openings being arranged in a suitable manner This allows, in particular, variants of the measurement electrode to be formed virtually without restriction, without the expenditure on production being increased. The material usage when producing the measurement electrode, in particular the use of conductive material for the conductor, can be kept low by virtue of a suitable design.

The fastening of the measurement electrode to a bodywork component of a motor vehicle, in particular to a mounting carrier which can be mounted on a bodywork component of this kind, can be implemented with a low level of expenditure by way of the solution as proposed. In the simplest case, the threading openings are additionally used in order to bring the measurement electrode into fixing engagement with the bodywork component or the mounting carrier. In principle, mounting openings which are provided in the carrier structure in addition to the threading openings can also be provided.

In various embodiments, the opening cross section of the threading openings is greater than the respective conductor cross section. Therefore, the largely force-free threading of the relevant conductor of the conductor structure as discussed above can be realized without additional expenditure on production.

Various embodiments relate to the laying of the relevant conductor of the conductor structure on the carrier structure. In an embodiment, the relevant conductor of the conductor structure runs alternately on opposite flat sides of the carrier structure owing to the threading through the threading openings.

As a result, firstly good fixing of the relevant conductor and a largely straight profile of the conductor can be realized when the conductor is not slightly bent in the region of the threading openings. This results in a uniform electrical behavior of the measurement electrode along the profile of the conductor in respect of proximity sensing. In this embodiment, the laying of the conductor is similar to a weaving process.

In various embodiments, however, the laying of the conductor is primarily based on a sewing process. Here, in one variant, a first conductor of the conductor structure, starting from a first flat side of the carrier structure, is threaded through the threading openings, whereas at least one second conductor of the conductor structure, on the second side of the carrier structure, is threaded through the loops on the other hand Particularly effective securing of the conductor structure to the carrier structure is realized therefore.

Various embodiments relate to design variants of the conductor structure itself. A particularly cost-effective design involves designing the relevant conductor of the conductor structure as an individual wire conductor.

Various embodiments for the design of the carrier structure are described herein. Specifically, the design of the carrier structure in said claim as a film structure can be implemented in a cost-effective manner and, at the same time, with a high degree of mechanical robustness.

In accordance with some embodiments, the capacitive proximity sensor of a motor vehicle, which capacitive proximity sensor has a measurement controller and a measurement electrode as proposed. Reference may be made to all embodiments relating to the measurement electrode as proposed.

In some embodiments, a bodywork component of a motor vehicle, to which a proximity sensor as proposed is fastened. Here, the fastening can be provided directly on the bodywork component or, as discussed above, by means of a mounting carrier. In this case too, reference may be made to all embodiments relating to the measurement electrode as proposed and to the proximity sensor as proposed.

In accordance with some embodiments, a method for producing a measurement electrode as proposed is disclosed. An important point according to the method as proposed is that at least one conductor of the electrical conductor structure is threaded through a plurality of threading openings. As explained above in relation to the first-mentioned teaching, the design and size of the measurement electrode can be adjusted in a simple manner by the position of the threading openings being selected in an appropriate manner The expenditure on production is significantly reduced by the method as proposed since largely force-free threading is possible with a suitable design of the threading openings.

An embodiment relates to producing the threading openings. In particular, the process of producing the threading openings by punching as proposed herein allows simple automated production of the threading openings, for example in a punching and rolling process. In a punching and rolling process of this kind, the carrier structure which does not yet have any threading openings is guided between two rollers, of which at least one roller has corresponding punching stamps. The expenditure on production associated with the production of the threading openings is very low.

Various embodiments relate to the production of measurement electrodes as described above and elsewhere herein. In this respect, reference may be made to all of the embodiments as disclosed herein.

An embodiment allows production of the measurement electrode as proposed in a particularly simple manner, even with a complex design of the conductor structure. The basic idea here is that of deforming the carrier structure before the threading of the relevant conductor such that at least two threading openings are in alignment with one another. As a result, the relevant conductor of the conductor structure can be threaded through at least two, such as a plurality of, threading openings, which are in alignment with one another, by way of the same threading movement.

An embodiment provides a measurement electrode for a capacitive proximity sensor of a motor vehicle, having an electrical conductor structure and having a flat carrier structure for holding the conductor structure, where a plurality of threading openings are provided in the carrier structure, at least one conductor of the conductor structure being threaded through said plurality of threading openings.

In various embodiments, the opening cross section of the threading openings is larger in respect of area than the respective conductor cross section, or wherein the opening cross section of the threading openings before threading of the respective conductor through the threading openings is smaller in respect of area than the respective conductor cross section, or wherein the opening cross section of the threading openings corresponds in respect of area to the respective conductor cross section.

In various embodiments, at least one conductor of the conductor structure runs alternately on opposite flat sides of the carrier structure owing to the threading through the threading openings.

In various embodiments, at least one first conductor of the conductor structure, starting from a first flat side of the carrier structure, and at least one second conductor of the conductor structure, starting from the second flat side of the carrier structure, are in fixing engagement with one another via the threading openings, such as wherein the first and second conductors of the conductor structure are twisted together, in particular knotted together, further such as wherein the first and second conductors of the conductor structure are connected to one another, further wherein the first and second conductors of the conductor structure together form a conductor which is composed of a single material.

In various embodiments, at least a first conductor of the conductor structure has loops which are threaded, starting from a first flat side of the carrier structure, through the threading openings, such as wherein at least one second electrical conductor of the conductor structure is threaded on the second flat side of the carrier structure through the loops and therefore secures the loops to the carrier structure.

In various embodiments, at least one conductor of the conductor structure, which conductor is threaded through the threading openings, is formed from a flexible, in particular from an elastically flexible or from a pliable, material, or wherein at least one conductor of the conductor structure, which conductor is threaded through the threading openings, is formed from a rigid material.

In various embodiments, at least one conductor of the conductor structure, which conductor is threaded through the threading openings, is designed as an individual wire conductor, in particular with a round or flat wire cross section, or as a braided conductor.

In various embodiments, the carrier structure is a flat profile, or wherein the carrier structure is a film structure.

In various embodiments, at least one conductor of the conductor structure, which conductor is threaded through the threading openings, runs in a straight line beyond at least two of these threading openings, or wherein at least one conductor of the conductor structure, which conductor is threaded through the threading-in openings, runs, in particular in an alternating manner, with a bend beyond at least two of these threading openings.

In various embodiments, at least one conductor of the conductor structure, which conductor is threaded through the threading openings, runs in a meandering manner

In various embodiments, the measurement electrode, in the mounted state, is fastened to a bodywork component of the motor vehicle by means of the carrier structure, such as wherein the fastening is a cohesive fastening and/or an interlocking fastening and/or a force-fitting fastening.

An embodiment provides a capacitive proximity sensor of a motor vehicle having a measurement controller and at least one measurement electrode as described herein.

An embodiment provides a bodywork component of a motor vehicle, to which a proximity sensor as described herein is fastened.

An embodiment provides a method for producing a measurement electrode as described herein, wherein at least one electrical conductor of the conductor structure is/are threaded through a plurality of threading openings.

In various embodiments, before the threading of the conductor of the conductor structure, the carrier structure is provided with threading openings which already exist, or wherein, before the threading of the conductor of the conductor structure, the threading openings are made in the carrier structure, such as wherein the threading openings are made in the carrier structure by means of punching, cutting, piercing or the like, such as wherein the threading openings are made in the carrier structure by means of a punching and rolling process.

In various embodiments, at least one conductor of the conductor structure is threaded through the threading openings in such a way that the conductor runs alternately on opposite flat sides of the carrier structure.

In various embodiments, at least one first conductor of the conductor structure, starting from a first flat side of the carrier structure, and at least one second conductor of the conductor structure, starting from the second flat side of the carrier structure, are brought into fixing engagement with one another via the threading openings, such as wherein the first and second conductors of the conductor structure are twisted together, in particular knotted together.

In various embodiments, loops are made in at least one first conductor of the conductor structure, said loops being threaded, starting from a first flat side of the carrier structure, through the threading openings, such as wherein at least one second electrical conductor of the conductor structure is threaded, on the second flat side of the carrier structure, through the loops and therefore the loops are secured to the carrier structure.

In various embodiments, the carrier structure, before the threading of at least one conductor of the conductor structure, is deformed, in particular folded, in such a way that at least two threading openings are in alignment with one another, such as wherein at least one conductor of the conductor structure is threaded through the at least two threading openings, which are in alignment with one another, by way of the same threading movement.

### BRIEF DESCRIPTION OF THE DRAWINGS

The disclosure will be explained in more detail below with reference to a drawing which illustrates only exemplary embodiments. In the drawing:

FIG. 1 shows the trunk region of a motor vehicle having a bodywork component as proposed which has a proximity sensor as proposed having a measurement electrode as proposed,

FIG. 2 shows the measurement electrode of the proximity sensor according to FIG. 1 a) during production and b) in the produced state,

FIG. 3 shows a second embodiment of a measurement electrode of the proximity sensor according to FIG. 1 a) during production and b) in the produced state, and

FIG. 4 shows a third embodiment of a measurement electrode of the proximity sensor according to FIG. 1 a) during production and b) in the produced state.

### DETAILED DESCRIPTION

The measurement electrode 1 for a capacitive proximity sensor 2 can be used for a variety of applications in a motor vehicle. Depending on the design, said measurement electrode allows detection by sensor of the presence and/or the movement of an object or of a user. Detection by sensor is based on a change in capacitance in the measurement electrode 1 in relation to ground or in relation to a further measurement electrode, which change in capacitance can be easily electronically detected. Here, the proximity sensor 2 serves to detect an operator control event, specifically a predetermined foot movement of a user, wherein the detection by sensor of the operator control event triggers motorized opening of the trunk lid 3 of the motor vehicle. Another exemplary application is collision identification for motor vehicle hatches.

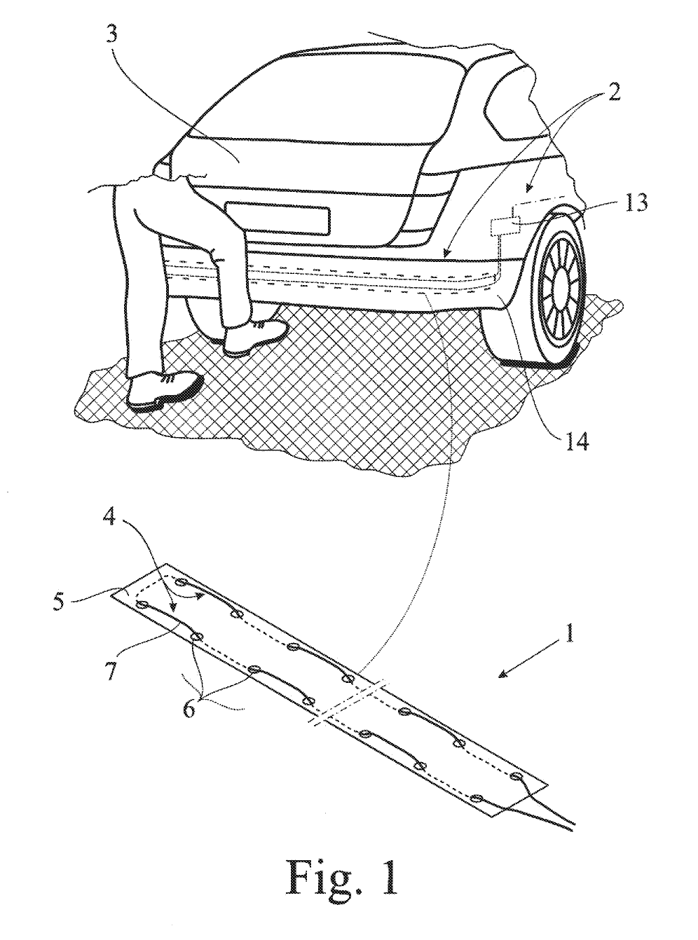

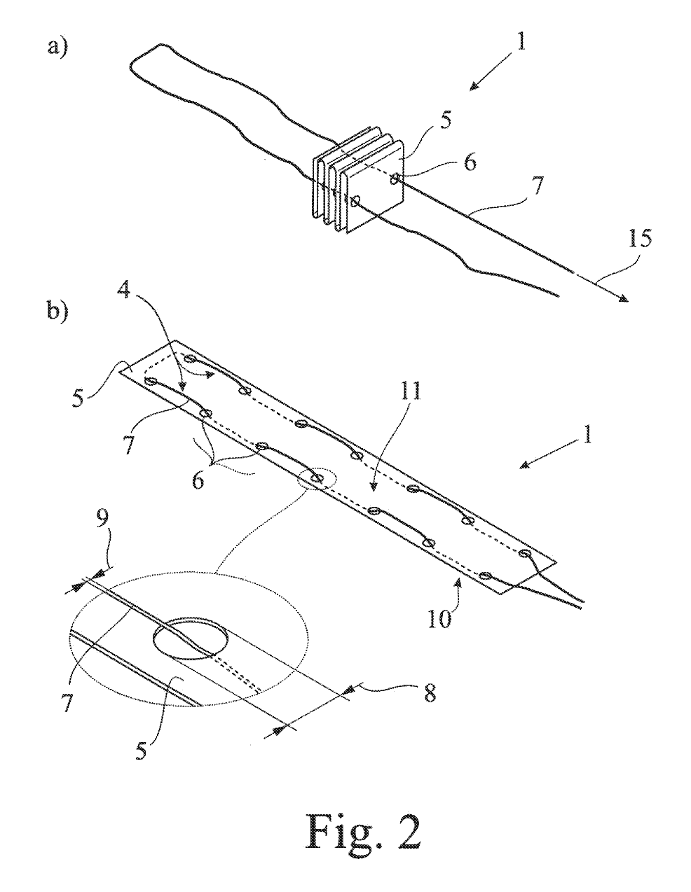

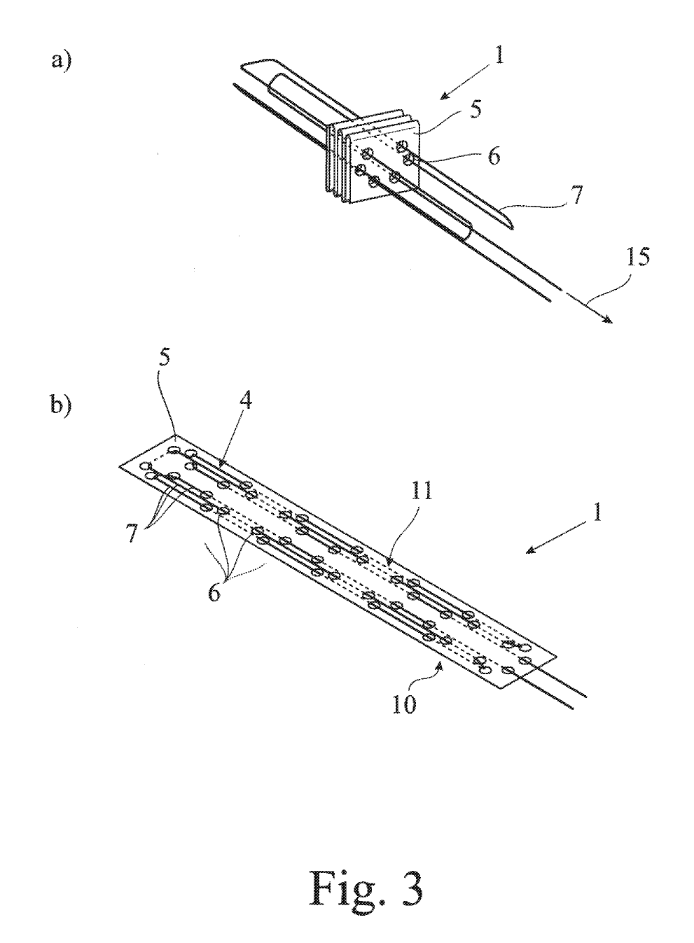

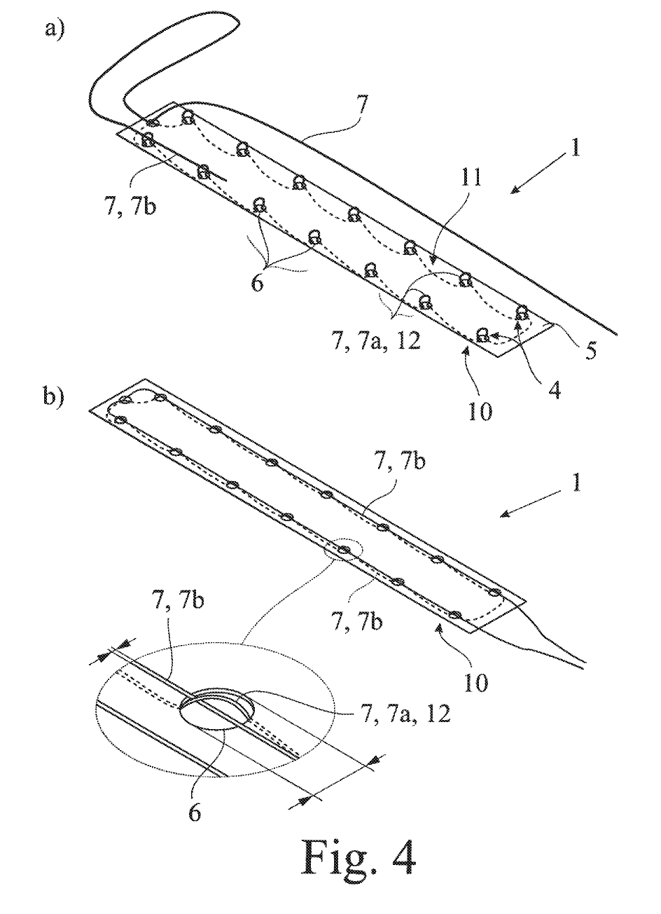

FIG. 1 and FIG. 2 show that the measurement electrode 1 has an electrical conductor structure 4 and a flat carrier structure 5 for holding the conductor structure 4. Alternative exemplary embodiments relating to the design of the measurement electrode 1 are shown in the illustrations according to FIG. 3 and FIG. 4. All of the embodiments relating to the different exemplary embodiments of the measurement electrode 1 apply in an alternately corresponding manner

A plurality of threading openings 6, through which at least one conductor 7 of the electrical conductor structure 4 is threaded, are provided in the carrier structure 5. A single conductor 7 is always provided in the illustrated exemplary embodiments. All of the relevant embodiments apply in a corresponding manner to measurement electrodes which have two or more separate associated conductors.

It is further provided in all of the illustrated exemplary embodiments that the opening cross section 8 of the threading openings 6 is larger in respect of area than the respective conductor cross section 9. Therefore, the largely force-free threading of the relevant conductor 7 as discussed further above can be readily realized. The opening cross section 8 can be at least 1.5 times, or at least 2 times, the size of the conductor cross section 9 in respect of area.

However, in principle, it can also be provided that the opening cross section 8 of the threading openings 6 before the threading of the respective conductor 7 is smaller in respect of area than the respective conductor cross section 9. Therefore, the threading is increased on account of the increased friction between the carrier structure 5 and the relevant conductor 7. However, this results in particularly good fixing of the conductor structure 4 to the carrier structure 5. As an alternative, it can also be provided that the opening cross section 8 of the threading openings 6 corresponds in respect of area to the respective conductor cross section 9, this representing, in principle, a good compromise between the two last-mentioned alternatives.

FIGS. 2 to 4 show different advantageous variants for the laying of the relevant conductor 7 on the carrier structure 5.

In the embodiment shown in FIG. 2, the relevant conductor 7 of the conductor structure 4 runs alternately on opposite flat sides 10, 11 of the carrier structure 5 owing to the threading through the threading openings 6. Accordingly, the conductor structure 4 is connected to the carrier structure 5 in the manner of a weaving process here. The same principle is used in the embodiment illustrated in FIG. 3, in which, however, a meandering profile, which is still to be explained, of the relevant conductor 7 is produced.

However, a first conductor 7a and a second conductor 7b, which here complement one another so as to form a single conductor 7 which is composed of a single material, are provided in the embodiment illustrated in FIG. 4. Accordingly, the first conductor 7a is a first conductor section of the conductor 7, while the second conductor 7b is a second conductor section of the conductor 7. Specifically, it is the case here that the first conductor 7a of the conductor structure 4, starting from a first flat side 10 of the carrier structure 5, and the second conductor 7b of the conductor structure 4, starting from the second flat side 11 of the carrier structure 5, are in fixing engagement with one another via the threading openings 6. FIG. 4b shows that the first conductor 7a and the second conductor 7b of the conductor structure 4 are twisted together. Depending on the manner of the laying of the relevant conductor 7, the first conductor 7a can also be knotted with the second conductor 7b.

As explained above, the first conductor 7a and the second conductor 7b of the conductor structure 4 are connected to one another in such a way that both conductors 7a, 7b complement one another so as to form one conductor 7. In particular, the first and second conductors 7a, 7b of the conductor structure 4 together form a conductor which is composed of a single material, as has been discussed above.

Particularly good fixing of the conductor structure 4 to the carrier structure 5 results in the embodiment illustrated in FIG. 4. The reason for this is that the conductor 7 which is arranged on the flat side 10, that is to say the first conductor 7a here, has loops 12 which, starting from the first flat side 10 of the carrier structure 5, are threaded through the threading openings 6. In this case, the second conductor 7b of the conductor structure 4 is threaded on the second flat side 11 of the carrier structure 5 through the loops 12 and therefore secures the loops 12 to the carrier structure 5. Here, the conductor structure 4 is fixed by the conductor structure 4 itself by virtue of the loops 12 which start from the flat side 10 being locked to a certain extent by the conductor 7 which starts from the flat side 11. As a result, the conductor structure 4 is secured to the carrier structure 5 with a low level of structural expenditure.

A wide variety of refinements of the conductor 7 are feasible depending on the planned laying of the relevant conductor 7. Here, the conductor 7 is formed from a flexible material. In this case, said material can be a material which is designed to be elastically flexible at least over a predetermined deformation region. However, as an alternative, it can also be provided that the conductor 7 is formed from a pliable material.

In principle, it may also be advantageous that the relevant conductor 7 is formed from a rigid material.

In the illustrated exemplary embodiments, the conductor 7 of the conductor structure 4, which conductor is threaded through the threading openings 6, is designed as an individual wire conductor with a round wire cross section. As an alternative, a flat wire cross section is also feasible here. As a further alternative, the conductor 7 can be designed as a braided conductor which is made up of a large number of conductor fibers. In the last-mentioned case, the result is a pliable design of the conductor 7 as discussed above, so that simple threading results, even with narrow bending radii.

Various advantageous variants are also feasible for the material of the conductor 7 which is threaded through the threading openings 6. Said material can be a copper material, a brass material, a steel material or the like. In order to be largely uninfluenced by environmental conditions such as the ingress of moisture and fluctuating temperatures, the relevant conductor 7 is formed from a stainless steel material in a refinement.

Here, the conductor 7 of the conductor structure 4, which conductor is threaded through the threading openings 6, is surrounded by an insulating sheathing, so that further insulation of the measurement electrode 1, such as encapsulation of the measurement electrode 1 by means of a cast resin for example, is not required. An insulating sheathing of this kind can be, in principle, a plastics sheathing As an alternative, the insulating sheathing can also be an insulating coating which is applied to the conductor 7. A particularly cost-effective realization results in the last-mentioned case.

In the illustrated exemplary embodiments, the carrier structure 5 as such is of pliable design. Therefore, the measurement electrode 1 can be flexibly matched to any desired shapes. However, it is also feasible that the carrier structure 5 as such is of rigid design, this further simplifying handling of the carrier structure 5.

The carrier structure 5 may be, in principle, a flat profile which can be flexible in the above manner In this case, various plastics materials can be used, such as PVC (polyvinyl chloride) or the like for example. It is also feasible that carbon fiber composite materials are used here. Finally, given sufficient insulation of the conductor structure 5, electrically conductive materials can also be used, for example aluminum or the like. In all of the above cases, the required mechanical robustness is achieved with a low weight.

The carrier structure 5 may also be a film structure. Here, the film structure likewise consists of a plastics material, in particular of PE (polyethylene) or the like. In a refinement, the present carrier structure 5 is a flexible film structure which has a certain degree of mechanical stiffness in order to ensure good handleability. However, as an alternative, the carrier structure 5 may also be a textile structure.

Here, the shaping of the opening cross section 8 of the threading openings 6 is matched to the conductor cross section 9. Here, the opening cross section 8 is a round opening cross section, while the conductor cross section 9 is likewise a round cross section. This matching allows simple threading of the relevant conductor 7, without jamming between the conductor 7 and the threading opening 6.

In principle, it can be provided that the conductor 7 of the conductor structure 4 which is threaded through the threading openings 6 runs in a straight line beyond at least two of these threading openings 6. This is associated with a particularly easily reproducible electrical behavior of the measurement electrode 1. However, in the case of the illustrated exemplary embodiments, the conductor 7 of the conductor structure 4, which conductor is threaded through the threading openings 6, here alternately, runs with a bend beyond at least two of these threading openings 6. This allows particularly simple fixing of the conductor structure 4 to the carrier structure 5.

As explained further above, the position of the threading openings 6 determines the design and size of the measurement electrode 1. In this case, an elongate measurement electrode 1, illustrated in the drawing, can be produced by the threading openings 6 being arranged in at least one row, in two rows, or in more than two rows, in each case along the longitudinal extent of the measurement electrode 1. However, it is also feasible, in principle, that the threading openings 6 are arranged on a geometric line of which the profile differs from a straight profile.

In the case of the embodiments illustrated in FIGS. 2 and 4, two conductor sections which run substantially parallel in relation to one another over the longitudinal extent of the measurement electrode 1 are produced. Here, more than two sections which run parallel in relation to one another in such a way can also be provided. In this sense, it is possible to readily achieve a meandering profile of the conductor 7 of the conductor structure 4 which is threaded through the threading openings 6 by way of the solution as proposed, as is shown in FIG. 3.

In the embodiment illustrated in FIG. 1, the proximity sensor 2 has a measurement controller 13. In FIG. 1, the measurement controller 13 is arranged separately from the measurement electrode 1. However, as an alternative, it can also be provided that at least a portion of the measurement controller 13 is arranged on the carrier structure 5. The measurement controller 13 is electrically coupled to the measurement electrode 1 and serves to generate and/or pre-evaluate sensor signals.

In this connection, it may be pointed out that the carrier structure 5 in the illustrated exemplary embodiments is of single-layer design. However, it is also feasible, in principle, that the carrier structure 5 consists of a plurality of layers, an electrical conductor 7 of the conductor structure 4 being applied to each of said layers. Therefore, measurement electrodes 1 with a complex structure, but at the same time with a low level of expenditure on production, can be produced.

The measurement electrode 1 as proposed is, in the mounted state, fastened to a bodywork component 14, here a fender, of the motor vehicle by means of the carrier structure 5. The bodywork component 14 may be any bodywork component of the motor vehicle. By way of example, the bodywork component 14 holding the measurement electrode 1 can be a trunk lid 3 as discussed above, a side door, an engine hood or the like, of the motor vehicle.

In a refinement, fastening of the measurement electrode 1 to the bodywork component 14 is cohesive fastening. In this case, an adhesive layer or a layer comprising an elastic material which is adhesive on both sides can be arranged between the carrier structure 5 and the bodywork component 14.

As an alternative or in addition, the fastening may be interlocking fastening. Here, the carrier structure 5 has fastening openings through which the fastening domes of the bodywork component 14 protrude. The fastening openings may be the threading openings 6 discussed above which have a double use in this respect. However, the fastening openings can also be provided in addition to the threading openings 6.

Finally, the fastening of the measurement electrode 1 to the bodywork component 14 may also be force-fitting fastening. To this end, a corresponding clamping apparatus or the like can be provided on the bodywork component 14.

In principle, a mounting carrier already discussed and to which the measurement electrode 1 is fastened in the above manner can also be associated with the bodywork component 14. This results in a particularly advantageous assembly in as much as the measurement electrode 1 is initially fastened to the mounting carrier, so that the mounting carrier can then be fastened to the bodywork component 14 together with the measurement electrode 1.

According to a further teaching which has independent significance, the capacitive proximity sensor 2 of the motor vehicle as such is disclosed. The proximity sensor 2 has, in addition to the measurement controller 13 discussed above, at least one measurement electrode 1 as proposed. In this respect, reference may be made to all embodiments relating to the measurement controller 13 on the one hand and relating to the measurement electrode 1 on the other hand

According to a further teaching which likewise has independent significance, the bodywork component 14 of the motor vehicle, to which bodywork component a proximity sensor 2 as proposed is fastened, as such is disclosed. In this respect, reference may be made to all embodiments relating to the proximity sensor 2 as proposed.

According to a further teaching, which likewise has independent significance, a method for producing a measurement electrode 1 as proposed is disclosed.

It is important according to the further teaching which relates to the production method for the measurement electrode 1, that the relevant conductor 7 of the conductor structure 4 is threaded through a plurality of threading openings 6. The advantage of the threading openings 6 which already exist before the threading of the conductor 7 has already been explained further above.

The threading of the relevant conductor 7 can be performed, in principle, by means of a needle, by means of a weaving shuttle, by means of a gripper or even by means of an air stream.

As explained further above, a carrier structure 5 in which threading openings 6 are already present is provided before the threading operation. In this case, it may be advantageous that the threading openings 6 are already produced as part of the production of the carrier structure 5 itself. This is the case particularly when the carrier structure 5 is a textile structure in the case of which the threading openings 6 can be, for example, woven or knitted.

However, the threading openings 6 can be made in the existing carrier structure 5 before the threading of the relevant conductor 7 of the conductor structure 4. The threading openings 6 can further be made in the carrier structure 5 by means of punching, cutting, piercing or the like. The threading openings 6 are produced in a particularly simple manner by the threading openings 6 being made in the carrier structure 5 by means of a punching and rolling process.

The embodiment illustrated in FIG. 2 can be realized in accordance with the method as proposed by at least one conductor 7 of the conductor structure 4 being threaded through the threading openings 6 in such a way that the conductor 7 runs alternately on opposite flat sides 10, 11 of the carrier structure 5.

For the purpose of realizing the measurement electrode 1 illustrated in FIG. 4, it is provided, as already indicated further above, that at least one first conductor 7a of the conductor structure 4, starting from a first flat side 10 of the carrier structure 5, and at least one second conductor 7b of the conductor structure 4, starting from the second flat side 11 of the carrier structure 5, are brought into fixing engagement with one another via the threading openings 6. In this case, the first and second conductors 7a, 7b of the conductor structure 4 can be twisted together, in particular knotted together.

Specifically, production of the measurement electrode 1 illustrated in FIG. 4 takes place such that loops 12 which are threaded through the threading openings 6 from a first flat side 10 of the carrier structure 5 are made in at least one first conductor 7a of the conductor structure 4. In this case, at least one second electrical conductor 7b of the conductor structure 4 is threaded through the loops 12 on the second flat side 11 of the carrier structure 5 and therefore secures the loops 12 to the carrier structure 5.

FIG. 4a shows how the loops 12 are threaded through the threading openings 6 and how the second conductor 7b is, in turn, threaded through the loops 12. FIG. 4b shows, in contrast, the finished measurement electrode 1 in which the conductor 7 has been slightly tightened.

FIGS. 2a and 3a show a variant for the threading of the relevant conductor 7 through the threading openings 6. Here, it is provided that the carrier structure 5 is deformed, here folded, before the threading of at least one conductor 7 of the conductor structure 4 in such a way that at least two threading-in openings 6 are in alignment with one another. This creates the possibility that the relevant conductor 7 of the conductor structure 4 is threaded through the at least two threading-in openings 6 which are in alignment with one another by way of the same threading movement 15. This is shown in FIG. 2a for two conductor sections which run in parallel, while FIG. 3a shows this for a total of six conductor sections which run in a meandering manner After threading of the relevant conductor 7 through the threading openings 6 in this way, the carrier structure 5 can be deformed back into its original shape, as is shown in FIGS. 2b and 3b. It is clear from the illustrations in FIGS. 2 and 3 that the threading in said figures of the relevant conductor 7 through the threading openings 6 can be readily implemented in an automated manner

Finally, it may be noted that the measurement electrode 1 for a capacitive proximity sensor can also be realized in an entirely different manner For example, it is feasible that the measurement electrode 1 is punched out of a metal sheet, so that the measurement electrode 1 is in the form of a sheet metal strip to a certain extent. In principle, the measurement electrode 1 can also be formed from a plurality of sheet metal strips. Furthermore, the measurement electrode 1 can also have a complex geometric structure in the manner of a leadframe. The metal sheet which forms the basis for the measurement electrode 1 can be provided as a brass sheet, as a copper sheet, as a bronze sheet, as a steel sheet, as a tin sheet or the like.

What is claimed is:

1. A measurement electrode for a capacitive proximity sensor of a motor vehicle, comprising:
an electrical conductor structure and a flat carrier structure for holding the conductor structure,
wherein the flat carrier structure comprises a plurality of threading openings, and
wherein at least one conductor of the conductor structure is threaded through the plurality of threading openings.

2. The measurement electrode as claimed in claim 1, wherein an opening cross section of the threading openings is larger in respect of area than the respective conductor cross section, or wherein the opening cross section of the threading openings before threading of the respective conductor through the threading openings is smaller in respect of area than the respective conductor cross section, or wherein the opening cross section of the threading openings corresponds in respect of area to the respective conductor cross section.

3. The measurement electrode as claimed in claim 1, wherein at least one conductor of the conductor structure runs alternately on opposite flat sides of the carrier structure owing to the threading through the threading openings.

4. The measurement electrode as claimed in claim 1, wherein at least one first conductor of the conductor structure, starting from a first flat side of the carrier structure, and at least one second conductor of the conductor structure, starting from the second flat side of the carrier structure, are in fixing engagement with one another via the threading openings.

5. The measurement electrode as claimed in claim 1, wherein at least a first conductor of the conductor structure has loops which are threaded, starting from a first flat side of the carrier structure, through the threading openings.

6. The measurement electrode as claimed in claim 1, wherein at least one conductor of the conductor structure, which conductor is threaded through the threading openings, is formed from a flexible or from a pliable, material, or wherein at least one conductor of the conductor structure, which conductor is threaded through the threading openings, is formed from a rigid material.

7. The measurement electrode as claimed in claim 1, wherein at least one conductor of the conductor structure, which conductor is threaded through the threading openings, is designed as an individual wire conductor, or as a braided conductor.

8. The measurement electrode as claimed in claim 1, wherein the carrier structure is a flat profile, or wherein the carrier structure is a film structure.

9. The measurement electrode as claimed in claim 1, wherein at least one conductor of the conductor structure, which conductor is threaded through the threading openings, runs in a straight line beyond at least two of these threading openings, or wherein at least one conductor of the conductor structure, which conductor is threaded through the threading-in openings, runs with a bend beyond at least two of these threading openings.

10. The measurement electrode as claimed in claim 1, wherein at least one conductor of the conductor structure, which conductor is threaded through the threading openings, runs in a meandering manner

11. The measurement electrode as claimed in claim 1, wherein the measurement electrode, in the mounted state, is fastened to a bodywork component of the motor vehicle by the carrier structure.

12. A capacitive proximity sensor of a motor vehicle comprising a measurement controller and at least one measurement electrode as claimed in claim 1.

13. A bodywork component of a motor vehicle, to which a proximity sensor as claimed in claim 12 is fastened.

14. A method for producing a measurement electrode as claimed in claim 1, wherein at least one electrical conductor of the conductor structure is/are threaded through a plurality of threading openings.

15. The method as claimed in claim 14, wherein, before the threading of the conductor of the conductor structure, the carrier structure has threading openings which already exist, or wherein, before the threading of the conductor of the conductor structure, the threading openings are made in the carrier structure.

16. The method as claimed in claim 14, wherein at least one conductor of the conductor structure is threaded through the threading openings in such a way that the conductor runs alternately on opposite flat sides of the carrier structure.

17. The method as claimed in claim 14, wherein at least one first conductor of the conductor structure, starting from a first flat side of the carrier structure, and at least one second conductor of the conductor structure, starting from the second flat side of the carrier structure, are brought into fixing engagement with one another via the threading openings, wherein the first and second conductors of the conductor structure are twisted together.

18. The method as claimed in claim 14, wherein loops are made in at least one first conductor of the conductor structure, the loops being threaded, starting from a first flat side of the carrier structure, through the threading openings, wherein at least one second electrical conductor of the conductor structure is threaded, on the second flat side of the carrier structure, through the loops and therefore the loops are secured to the carrier structure.

19. The method as claimed in claim 14, wherein the carrier structure, before the threading of at least one conductor of the conductor structure, is deformed in such a way that at least two threading openings are in alignment with one another.

20. The measurement electrode as claimed in claim 5, wherein at least one second electrical conductor of the conductor structure is threaded on the second flat side of the carrier structure through the loops and therefore secures the loops to the carrier structure.
